(19) United States
(12) Patent Application Publication
(10) Pub. No.: US 2011/0079902 A1
(43) Pub. Date: Apr. 7, 2011

(54) SEMICONDUCTOR DEVICE

(76) Inventors: Takeshi SAKAMOTO, Osaka (JP); Katsumi Otani, Osaka (JP); Kimihito Kuwabara, Kyoto (JP)

(21) Appl. No.: 12/847,526

(22) Filed: Jul. 30, 2010

(30) Foreign Application Priority Data
Oct. 7, 2009 (JP) 2009-233448

(51) Int. Cl. H01L 23/488; H01L 23/31; H01L 23/48; H01L 23/373

(52) U.S. Cl. 257/738; 257/788; 257/778; 257/E23.11; 257/E23.124; 257/E23.023; 257/E23.01

(57) ABSTRACT

A semiconductor device has a wiring substrate provided with an external connecting terminal on a lower surface, a semiconductor chip mounted onto an upper surface of the wiring substrate, a cap-shaped heat dissipation member arranged on the upper surface of the wiring substrate so as to cover the semiconductor chip, a fixing pin for fixing the heat dissipation member onto the upper surface of the wiring substrate, and a heat transfer material sandwiched between a lower surface of the heat dissipation member just above the semiconductor chip and the upper surface of the semiconductor chip.

### CROSS-REFERENCE TO RELATED APPLICATION

This application claims priority to Japanese Patent Application No. 2009-233448 filed on Oct. 7, 2009, the disclosure of which including the specification, the drawings, and the claims is hereby incorporated by reference in its entirety.

### BACKGROUND

The present disclosure relates to heat dissipation structures of semiconductor devices.

In semiconductor devices to be incorporated into computers and home electrical appliances, heat values of semiconductor chips mounted into the devices abruptly increase due to high integration and heightening of functionality. When temperature of the semiconductor chips becomes high, malfunction occurs. For this reason, the malfunction caused by heat is repressed by a countermeasure against heat such as attaching of heat dissipation plates made of metal with high thermal conductivity to semiconductor chips.

As heat dissipation members, a heat spreader as single metallic plate arranged on a top surface of a semiconductor package, a heat sink having a lot of fins, a heat dissipation cap that covers side and upper portions of the semiconductor chips and the like are used.

In any cases, a material with high thermal conductivity such as grease or a heat transfer sheet is applied or arranged between a semiconductor chip as a heat generating source and a heat dissipation member, and thus heat dissipation from the semiconductor chip is not prevented. In this case, it is desirable that a thickness of the grease and the heat transfer sheet is as small and uniform as possible. It is known that when the thickness of the grease and the heat transfer sheet is large or nonuniform, a heat dissipation property is noticeably deteriorated.

FIG. 1A is a perspective view illustrating a conventional semiconductor device having a heat dissipation cap, and FIG. 1B is a cross-sectional view of the semiconductor device taken along line Ib-Ib shown in FIG. 1A (Japanese Patent Publication No. 2007-194543).

In the conventional semiconductor device, a semiconductor chip 101 is bonded to an upper surface of a wiring substrate 130 with it facing down, namely, a circuit formed surface facing the wiring substrate 130 by a solder bump 103. An underfill material 104 that reinforces bonding strength is poured into a gap between the semiconductor chip 101 and the wiring substrate 130.

An upper inner surface of the heat dissipation cap 112 contacts with an upper surface of the semiconductor chip 101 via a heat transfer material (not shown). Further, a part or an entire portion of a bottom surface of a side wall of the heat dissipation cap 112 is bonded to the upper surface of the wiring substrate 130 by a bonding adhesive 150. A heat generated from the semiconductor chip 101 transfers to the heat dissipation cap 112 via the heat transfer material, and is dissipated to the entire semiconductor device by the heat dissipation cap 112.

Another example of the conventional semiconductor device is such that a protrusion is provided on a lower portion of a side wall of the heat dissipation cap 112 toward the wiring substrate 130 (see Japanese Patent Publication No. 2007-165486). In this example, the provision of the protrusion makes the bottom surface of the side wall of the heat dissipation cap 112 directly contact with the wiring substrate 130, and the thickness of the bonding adhesive 150 between the bottom surface of the side wall of the heat dissipation cap 112 and the wiring substrate 130 is prevented from being asymmetrical, thereby improving a contact property of the upper surface of the upper portion of the heat dissipation cap 112 with the upper surface of the semiconductor chip 101.

### SUMMARY

In order to efficiently release a heat from the semiconductor chip 101 by means of the heat dissipation cap 112, it is necessary to narrow a gap between the upper inner surface of the heat dissipation cap 112 and the upper surface of the semiconductor chip 101 as much as possible. In general, the heat transfer material with high thermal conductivity such as grease or heat transfer sheet is arranged between the heat dissipation cap and the semiconductor chip, but it is important to arrange such a heat transfer material into a thin and uniform thickness.

In the semiconductor device shown in FIGS. 1A and 1B, it is difficult to apply the bonding adhesive 150 to the four bottom surfaces of the side walls of the heat dissipation cap 112 into the uniform thickness, and the thickness of the bonding adhesive 150 varies on each side. For this reason, the heat dissipation cap 112 easily inclines. When the heat dissipation cap 112 inclines, the distribution of the heat transfer material provided between the upper inner surface of the heat dissipation cap 112 and the upper surface of the semiconductor chip 101 becomes nonuniform, thereby deteriorating the heat dissipation property. Further, when the thickness of the bonding adhesive varies in individual semiconductor devices, the thickness of the heat transfer material varies in the semiconductor devices. For this reason, the management of a heat dissipation performance is difficult.

As described in Japanese Patent Application No. 2007-165486, when the protrusion is provided to the bottom portion of the side wall of the heat dissipation cap 112, the protrusion contacts with the wiring substrate 130, and thus the variation in the thickness of the bonding adhesive 150 is reduced. However, besides the variation in the thickness of the bonding adhesive 150, other factors that cause the variation in a distance between the upper inner surface of the heat dissipation cap 112 and the upper surface of the semiconductor chip 101 (namely, the thickness of the heat transfer material) are present. For this reason, also in the semiconductor device described in Japanese Patent Application No. 2007-165486, it is difficult to sufficiently reduce the variation in the thickness of the heat transfer material.

The heat generated from the semiconductor chip at the time of an operation of the present invention is effectively radiated, and the variation in the heat dissipation property in the device and the variation in the heat dissipation property among the devices can be reduced.

A semiconductor device according to one example of the present invention has a wiring substrate provided with an external connecting terminal on a lower surface, a semiconductor chip mounted onto an upper surface of the wiring substrate, a cap-shaped heat dissipation member arranged on the upper surface of the wiring substrate so as to cover the semiconductor chip, a fixing pin for fixing the heat dissipation member onto the upper surface of the wiring substrate, and a heat transfer material sandwiched between a lower surface of the heat dissipation member just above the semiconductor chip and an upper surface of the semiconductor chip.

In this constitution, since the heat dissipation cap is fixed onto the wiring substrate by the fixing pin, the heat dissipation cap hardly inclines with respect to the wiring substrate. Further, even if the wiring substrate is heated at a step of manufacturing the semiconductor device, its warpage is reduced by the fixing pin. For this reason, the non-uniformity of the thickness of the heat transfer material due to the warpage can be prevented. Therefore, the variation in the heat dissipation property in the semiconductor device can be reduced. Further, the variation in the heat dissipation property among the semiconductor devices can be also reduced.

Further, a heat transfer sheet sandwiched between the wiring substrate and the heat dissipation member is further provided, so that the heat transferred to the fixing pin can be effectively transferred to the wiring substrate. A tightening condition of the fixing pin is suitably adjusted, so that the heat dissipation cap can be effectively prevented from inclining with respect to the wiring substrate.

In the semiconductor device having the heat dissipation member according to the present invention, since the heat dissipation cap and the wiring substrate are fixed by the fixing pin, for example the tightening strength is suitably adjusted so that warpage of the wiring substrate is corrected and the thickness of the heat transfer material can be thin and uniform. For this reason, a heat dissipation performance can be improved, the variation in the device can be reduced, and the variation in the heat dissipation performance among the devices can be reduced.

### BRIEF DESCRIPTION OF THE DRAWINGS

FIG. 1A is a perspective view illustrating a conventional semiconductor device having a heat dissipation cap;

FIG. 1B is a cross sectional view of the semiconductor device taken along line Ib-Ib of FIG. 1A;

FIG. 2A is a plan view when the semiconductor device according to a first embodiment of the present invention is viewed from above a wiring substrate;

FIG. 2B is a cross sectional view of the semiconductor device taken along line IIb-IIb of FIG. 2A;

FIG. 3 is a cross sectional view illustrating the semiconductor device according to a modified example of the first embodiment;

FIG. 4 is a cross sectional view illustrating an end portion where a fixing pin is provided in the semiconductor device according to a second embodiment of the present invention;

FIG. 5 is a cross sectional view illustrating an end portion where the fixing pin is provided in the semiconductor device according to a third embodiment of the present invention; and

FIG. 6 is a cross sectional view illustrating the semiconductor device according to a fifth embodiment of the present invention.

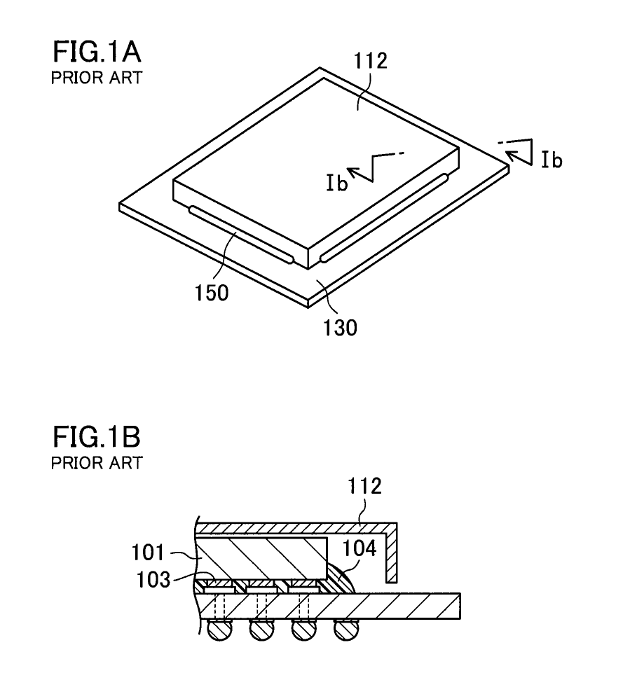

### DETAILED DESCRIPTION

Embodiments of the present invention are described below with reference to the drawings.

### First Embodiment

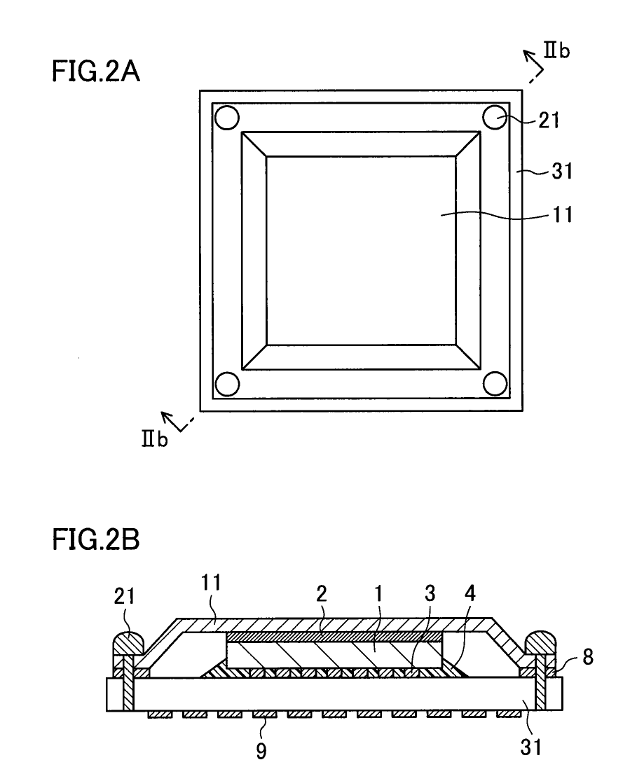

FIG. 2A is a plan view when a semiconductor device according to a first embodiment of the present invention is viewed from above a wiring substrate, and FIG. 2B is a cross sectional view of the semiconductor device taken along line Ith-Ith of FIG. 2A.

As shown in FIGS. 2A and 2B, the semiconductor device according to the first embodiment has a wiring substrate 31, a semiconductor chip 1, an underfill material 4, a heat dissipation cap (heat dissipation member) 11, a heat transfer material 2, a heat transfer sheet (heat transfer member) 8, a fixing pin (fixing member) 21. The wiring substrate 31 is provided with a bump (connecting member) 3 on its upper surface and a soldering ball 9 as an external connecting terminal on its rear surface. The semiconductor chip 1 is mounted to an upper surface of the wiring substrate 31 via the bump 3 with it facing down (a circuit formed surface facing the upper surface of the wiring substrate 31. The underfill material 4 fills a gap between the semiconductor chip 1 and the wiring substrate 31. The heat dissipation cap 11 is put on the upper surface of the wiring substrate 31 and covers the semiconductor chip 1. The heat transfer material 2 is provided on a rear surface (a surface facing the circuit formed surface) of the semiconductor chip 1, and thermally connects the semiconductor chip 1 and heat dissipation cap 11. The heat transfer sheet 8 is put between a peripheral portion of the heat dissipation cap 11 and the wiring substrate 31. The fixing pin 21 pierces the peripheral portion of the heat dissipation cap 11 and the heat transfer sheet 8, and fixes the heat dissipation cap 11 onto the wiring substrate 31. The “upper surface” and the “lower surface” of the wiring substrate 31 mean an upper surface and a lower surface in FIG. 2B, respectively. In FIG. 2B, the upper surface of the semiconductor chip 1 is the rear surface facing the circuit formed surface.

The wiring substrate 31 is a multilayer structured substrate where an insulating layer and a wiring layer are laminated. The insulating layer is made of, for example, a resin material, an organic polymeric material, or a ceramic material. Wiring made of a conductive material such as copper or aluminum is formed on the wiring layer. A solider resist layer (not shown) whose electrode portion is opened is provided on an upper surface and a lower surface of the wiring substrate 31. The wiring layers adjacent in an up-down direction are electrically connected through a via provided on the insulating layer.

The heat dissipation cap 11 has a convex portion. For example, when a center portion is a convex portion, the center portion has a structure such that it rises from its peripheral portion by means of working such as press working.

The bump 3 can be made by solder of various compositions, but may be made by gold or conductive resin. The bump 3 connects an electrode pad on the wiring substrate 31 and an electrode pad provided on the circuit formed surface of the semiconductor chip 1.

The underfill material 4 reinforces the bonding of the wiring substrate 31 and the semiconductor chip 1, and is made of a general material such as insulating resin.

Further, the heat transfer material 2 is grease, a heat transfer sheet and the like applied to or arranged on the rear surface of the semiconductor chip 1, and is made of a material with high thermal conductivity. Since the heat conductivity is inversely proportional to the thickness of the material, it is desirable that the heat transfer material 2 is formed on the rear surface of the semiconductor chip 1 into a thin and uniform thickness. A heat transfer material 2 contacts with a lower surface of a portion of the heat dissipation cap 11 just above the semiconductor chip 1, and the gap between the semiconductor chip 1 and the heat dissipation cap 11 is eliminated by the heat transfer material 2. As a result, a heat generated on the semiconductor chip 1 at the time of an operation of the semiconductor device can be efficiently transferred to the heat dissipation cap 11, and the transferred heat can be efficiently dissipated.

The heat transfer sheet 8 is an elastic high-heat dissipation insulating material that is provided in order to efficiently discharge the heat transferred to the heat dissipation cap 11 into the wiring substrate 31, and mostly silicone rubber or acrylic rubber is used as its material.

In the semiconductor device according to the first embodiment, differently from conventional semiconductor devices, a hole for passing the fixing pin 21 is provided on the heat dissipation cap 11, and a hole or a groove is provided also on the wiring substrate 31. The fixing pin 21 is screwed into the hole or groove so that the heat dissipation cap 11 is fixed onto the wiring substrate 31.

In the semiconductor device according to the first embodiment, since the heat dissipation cap 11 is fixed onto the wiring substrate 31 by the fixing pin 21, the heat dissipation cap 11 hardly inclines with respect to the wiring substrate 31. As a result, the thickness of the heat transfer material 2 is also approximately uniform on the entire rear surface of the semiconductor chip 1, and the heat can be dissipated uniformly via the heat dissipation cap 11.

Since a tightening condition of the fixing pin 21 can be adjusted, tightening strength of the fixing pin 21 is suitably adjusted so that warpage of the wiring substrate 31 can be corrected. Further, since the heat transfer material 2 can be fixed with a thinned state, the thickness of the heat transfer material 2 is made to be approximately uniform on the entire rear surface of the semiconductor chip 1 so that variation in a heat dissipation performance in the semiconductor device and the variation in the heat dissipation performance among the semiconductor devices can be reduced and further the heat dissipation performance can be improved.

The fixing pin 21 is made of, for example, insulating plastic, but it is desirable that the fixing pin is made of a material with excellent heat conductivity because the heat can be transferred to the wiring substrate 31 even via the fixing pin 21. The fixing pin 21 has a head portion exposed to the outside of the semiconductor device and a cylindrical portion inserted into at least the heat dissipation cap 11 and the heat transfer sheet 8. A diameter of the cylindrical portion is smaller than a diameter of the head portion.

In the semiconductor device according to the first embodiment, planar shapes of the heat dissipation cap 11 and the wiring substrate 31 are quadrate, and a hole for the fixing pin 21 is provided on each of four corners of the peripheral portion of the heat dissipation cap 11. However, a hole for screwing the fixing pin 21 is formed on a center portion of each side of the peripheral portion of the heat dissipation cap 11 in order to enhance adhesion between the heat dissipation cap 11 and the wiring substrate 31, and the fixing pin 21 may be mounted.

The heat dissipation cap 11 is made of metal with high thermal conductivity such as copper or aluminum, and its peripheral portion is, for example, flat and is approximately parallel with the upper surface of the wiring substrate 31. Due to such a shape of the heat dissipation cap 11, the heat dissipation cap 11 can be easily fixed by the fixing pin 21.

A step of attaching the heat dissipation cap 11 is described below with reference to FIG. 2B.

The convex portion is formed on a metal plate made of metal with excellent heat conductivity such as copper or aluminum by a general working method so that the heat dissipation cap 11 is prepared. The hole for passing the fixing pin 21 is formed in the peripheral portion of the heat dissipation cap 11. On the other hand, a through hole is formed in a position that is the peripheral portion of the wiring substrate 31 whose lower surface is formed with the soldering ball 9 and corresponds to the hole of the heat dissipation cap 11 by using a drill.

The semiconductor chip 1 is mounted onto the upper surface of the wiring substrate 31 with its circuit formed surface facing down. After the underfill material 4 is poured into the gap between the wiring substrate 31 and the semiconductor chip 1 and is cured, the heat transfer material 2 such as grease or a heat transfer sheet is applied to or arranged on the top surface of the semiconductor chip 1. The upper surface of the wiring substrate 31 is covered with the heat dissipation cap 11 with the heat transfer sheet 8 being sandwiched between the heat dissipation cap 11 and the wiring substrate 31. At this time, a position of the hole formed on the wiring substrate 31 is made to match with a position of the hole formed in the heat dissipation cap 11. Thermoset resin or the like is generally used as the underfill material 4. At this step, in order to cure the underfill material 4, both the semiconductor chip 1 and the wiring substrate 50 are put in a high-temperature environment, but after the underfill material 4 is cured, when it returns to room temperature, the semiconductor chip 1 and the wiring substrate 31 are warped due to mismatching of coefficients of thermal expansion in the respective materials. A warpage amount changes due to variation in a pouring amount of the underfill material 4, variation of the respective wiring substrates 31, or a wiring pattern. For this reason, it is difficult to reduce the generation of the warpage in the conventional semiconductor devices.

The fixing pin 21 is passed through the holes of the heat dissipation cap 11 and the wiring substrate 31, and the heat dissipation cap 11 is fixed onto the wiring substrate 31. At this time, a lower surface of the heat dissipation cap 11 just above the semiconductor chip 1 contacts with the heat transfer material 2, and the fixing pin 21 is tightened so that the thickness of the heat transfer material 2 becomes uniform.

Before the heat dissipation cap 11 is fixed by the fixing pin 21, the warpage shape of the semiconductor chip 1 and the wiring substrate 31 with the underfill material 4 being poured and cured, and a height from the upper surface of the wiring substrate 31 to the rear surface (upper surface) of the semiconductor chip 1, and a height of the convex portion when viewed from the peripheral portion of the heat dissipation cap 11 are measured in advance. In this state, the warpage amount of the wiring substrate 31 after the tightening of the fixing pin 21 and a height from the upper surface of the wiring substrate 31 to the top surface of the heat dissipation cap 11 are measured, so that the thickness of the heat transfer material 2 arranged between the semiconductor chip 1 and the upper inner surface of the heat dissipation cap 11 can be controlled. As a result, the heat dissipation property of the entire semiconductor device can be improved, and variation in heat dissipation performance can be reduced.

### Modified Example of the First Embodiment

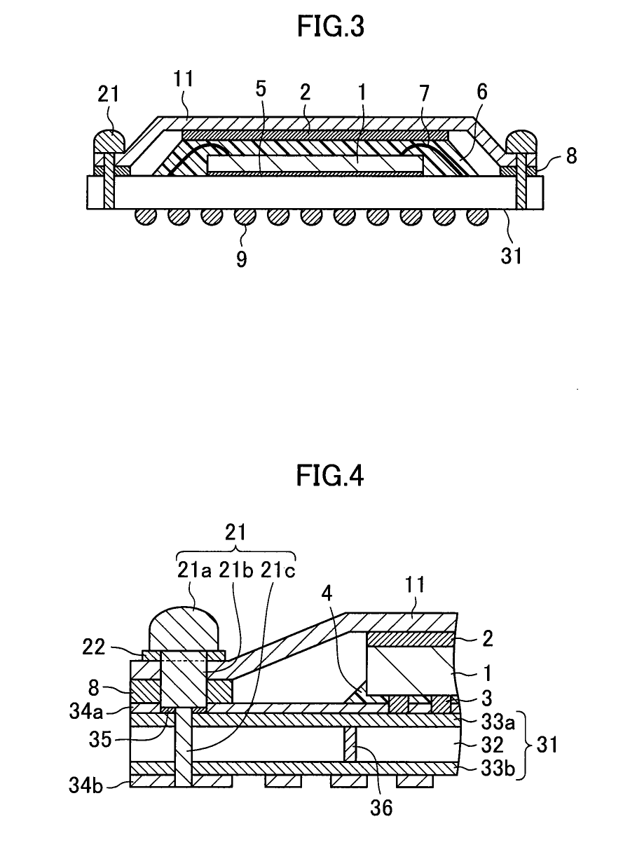

FIG. 3 is a cross sectional view illustrating the semiconductor device according to a modified example of the first embodiment. FIG. 3 illustrates the semiconductor device in the case where the semiconductor chip 1 is encapsulated by an encapsulation resin 6.

The semiconductor chip 1 is bonded to the upper surface of the wiring substrate 31 by a die bonding material 5 with the circuit formed surface facing up.

The electrode pad on the semiconductor chip 1 is electrically connected to the electrode pad provided on the upper surface of the wiring substrate 31 by a bonding wire 7. The semiconductor chip 1, the die bonding material 5, and the bonding wire 7 are encapsulated by the encapsulation resin 6. The heat transfer material 2 made of the similar material to that in the semiconductor device according to the first embodiment is mounted into a space between the upper surface of the encapsulation resin 6 and the upper inner surface (a ceiling portion of the convex portion) of the heat dissipation cap 11. That is to say, the heat transfer material 2 contacts with the lower surface of the heat dissipation cap 11 just above the semiconductor chip 1. Since the other parts of the constitution such as the shape and mounting position of the fixing pin 21 are similar to those in the semiconductor device according to the first embodiment shown in FIGS. 2A and 2B, the description thereof is omitted.

With the above constitution, when the fixing pin 21 is suitably tightened, the warpage of the wiring substrate 31 and the semiconductor chip 1 is reduced and the variation in the heat dissipation performance can be effectively reduced.

### Second Embodiment

FIG. 4 is a cross sectional view illustrating an end portion where the fixing pin is provided in the semiconductor device according to a second embodiment of the present invention.

In the semiconductor device according to the second embodiment, the wiring substrate 31 has a plate-shaped substrate material 32, a first wiring 33a formed on an upper surface of the substrate material 32, a second wiring 33b formed on a lower surface of the substrate material 32, and a via 36 for connecting the first wiring 33a and the second wiring 33b. Solder resist layers 34a and 34b are formed on the first wiring 33a and the second wiring 33b, respectively. The first wiring 33a and the second wiring 33b are formed also on the peripheral portion of the wiring substrate 31 into which the fixing pin 21 is inserted.

The fixing pin 21 is made of an insulator with excellent heat conductivity such as plastic, and includes a head portion 21a, a cylindrical portion 21b that pierces at least the heat dissipation cap 11 and the heat transfer sheet 8, and a thread portion 21c to be inserted into the wiring substrate 31. A diameter of the cylindrical portion 21b is smaller than a diameter of the head portion 21a and is larger than a diameter of the thread portion 21c. It is preferable that the thermal conductivity of the fixing pin 21 is higher than at least that of the substrate material 32 and the underfill material 4, and it is preferably 1.0 W/(m·k) or more, for example.

As to such a fixing pin 21, the heat dissipation cap 11 and the wiring substrate 31 are pressed by a bearing surface of the bottom surface of the head portion 21a. A spring washer for adjusting a height and a layer that is made of an elastic high-heat dissipation material such as silicone rubber are provided as a spacer 22 between the bearing surface and the heat dissipation cap 11. A length of the cylindrical portion 21b of the fixing pin 21 is shorter than a total thickness of the heat dissipation cap 11, the spacer 22, the heat transfer sheet 8, and the solder resist layer 34a on the upper surface of the wiring substrate 31 in a state that a stress is not applied. A difference between the thickness of the cylindrical portion 21b and the total thickness of the above members is not more than a sum of the thickness of the spacer 22, the thickness of the heat transfer sheet 8, and the thickness of the grease 35. For this reason, when the fixing pin 21 is tightened, the spacer 22 and the heat transfer sheet 8 contracts so that the bottom surface of the cylindrical portion 21b contacts with the first wiring 33a via the grease. A material with high heat conductivity is used as the grease 35. It is preferable that the grease 35 is provided because a heat can be transferred more effectively.

The heat generated from the semiconductor chip 1 diffuses to the heat dissipation cap 11. For this reason, the fixing pin 21 with excellent heat conductivity contacts with the wirings of the wiring substrate 31, so that the heat transferred to the heat dissipation cap 11 is transferred to the wiring substrate 31 and can be effectively dissipated. Particularly when the bottom surface of the cylindrical portion 21b contacts directly or indirectly with the first wiring 33a, the transferred heat can be transferred to the first wiring 33a made of metal with high thermal conductivity via the fixing pin 21. Further, since the heat diffuses from the first wiring 33a through the via 36 formed in the substrate material 32 to the second wiring 33b, the heat dissipation property of the entire semiconductor device can be improved as a result.

### Third Embodiment

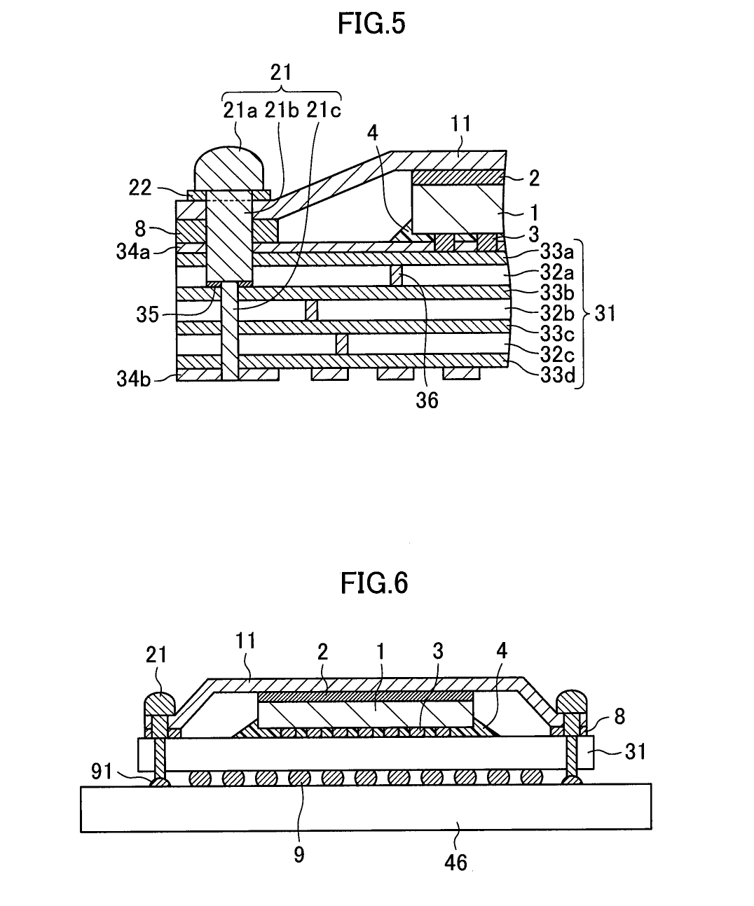

FIG. 5 is a cross sectional view illustrating the end portion where the fixing pin is provided in the semiconductor device according to a third embodiment of the present invention.

In the semiconductor device according to the third embodiment, the wiring substrate 31 is structured so that, for example, four wiring layers and three layers of substrate materials are laminated alternately. That is to say, the first wiring 33a, a first substrate material 32a, the second wiring 33b, a second substrate material 32b, a third wiring 33c, a third substrate material 32c, and a fourth wiring 33d are laminated in this order from above, so that the wiring substrate 31 is structured. The solder resist layers 34a and 35b are formed on the first wiring 33a and the fourth wiring 33d (the upper surface and the lower surface of the wiring substrate 31), respectively.

The structure and the composing material of the fixing pin 21 are approximately the same as those of semiconductor device according to the second embodiment, and the fixing pin 21 includes the head portion 21a, the cylindrical portion 21b, and the thread portion 21c.

The heat dissipation cap 11 and the wiring substrate 31 are pressed by the bearing surface of the bottom surface of the head portion 21a. A spring washer for adjusting the height and a layer made of an elastic high-heat dissipation material such as silicone rubber are provided as the spacer 22 between the bearing surface and the heat dissipation cap 11.

FIG. 5 illustrates an example that the bottom surface of the cylindrical portion 21b of the fixing pin 21 is brought into contact with the second wiring 33b, but the bottom surface of the cylindrical portion 21b may contacts with the other wirings. In the example shown in FIG. 5, the length of cylindrical portion 21b of the fixing pin 21 is shorter than the total thickness of the heat dissipation cap 11, the spacer 22, the heat transfer sheet 8, the solder resist layer 34a of the wiring substrate 31, the first wiring 33a, and the substrate material 32a in a state that a stress is not applied. A difference between the thickness of the cylindrical portion 21b and the total thickness of the above members is not more than the sum of the thickness of the spacer 22, the thickness of the heat transfer sheet 8, and the thickness of the grease 35. For this reason, when the fixing pin 21 is tightened, the spacer 22 and the heat transfer sheet 8 contracts, so that the bottom surface of the cylindrical portion 21b contacts with the first wiring 33a via the grease 35. In general, the wirings (second wiring 33b and the third wiring 33c) provided on an intermediate wiring layer of the wiring substrate 31 having the four-layered wiring are mostly used as a power supply line or a ground plane, and an area where this layer contacts with the fixing pin 21 is increased so that the heat dissipation performance can be improved.

Also when the bottom surface of the cylindrical portion 21b contacts with a wiring lower than the second wiring 33b, high-heat dissipation property can be obtained similarly to the structure shown in FIG. 5.

The shape of the fixing pin 21 is not limited to the example shown in FIG. 5, and the bottom surface of the cylindrical portion 21b may contact directly or indirectly with the wiring provide on one of the wiring layers except for the top wiring layer.

### Fourth Embodiment

FIG. 6 is a cross sectional view illustrating the semiconductor device according to a fourth embodiment of the present invention.

In the semiconductor device according to the fourth embodiment, an electrode pad (not shown) on the bottom surface side of the wiring substrate 31 is arranged into a matrix pattern, for example, and a BGA (ball grid array) type semiconductor device where the soldering ball 9 is an external connecting terminal. The semiconductor chip 1 is connected to the wiring substrate 31 by the similar method to that described in the first embodiment, but the semiconductor chip 1 may be mounted onto the wiring substrate 31 with the circuit formed surface facing up like the method according to the modified example of the first embodiment.

The fixing pin 21 does not have to be protruded from the lower side of the wiring substrate 31.

### Fifth Embodiment

The semiconductor device according to a fifth embodiment of the present invention is described with reference to FIG. 6.

The semiconductor device according to the fifth embodiment is mounted onto a mother board 46, and an electrode on the mother board is electrically connected to the electrode on the wiring substrate 31 via the soldering ball 9.

The fixing pin 21 protrudes from the lower side of the wiring substrate 31, and a length of the protruded portion is approximately equal to the height of the soldering ball 9. When the semiconductor device is soldered to be bonded onto the mother board 46, a solder paste 91 is provided on the mother board 46, and semiconductor device is bonded onto the mother board 46 so that the protruded portion of the fixing pin 21 contacts with the solder paste 91.

With this structure, the heat generated from the semiconductor chip 1 can be dissipated to the mother board 46 via the fixing pin 21, and the heat dissipation performance of the semiconductor device can be improved.

The semiconductor device described above is one example of the embodiments, the composing materials and the shapes of respective members may be suitably changed without departing from the scope of the present invention. For example, the fixing member is not limited to the fixing pin, and any member such as a split rivet may be used as long as it has a structure such that the heat dissipation cap can be fixed onto the wiring substrate. Further, the wiring substrate 31 may be structured so that three wiring layers and two layers of substrate material are laminated alternately, or five or more wiring layers and substrate materials are laminated alternately. That is to say, when N is defined as an integer of 2 or more, the wiring substrate 31 may be structured so that N layers of wiring layers and (N−1) layers of substrate materials are laminated alternately. At this time, when the bottom surface of the cylindrical portion 21b contacts directly or indirectly with the wiring of any one of the first to N wiring layers counted from the top, the heat can be effectively diffused to the wiring via the fixing pin 21.

The respective embodiments and the modified example may be suitably combined without departing from the scope of the present invention.

The present invention improves the heat dissipation property and reduces the variation in the heat dissipation performance in semiconductor devices where a heat value is large, and is effective particularly for the designs and the manufacturing methods of flip-chip type, land grid array (LGA) and ball grid array (BGA) type semiconductor devices.

What is claimed is:

1. A semiconductor device, comprising:
a wiring substrate;
a semiconductor chip mounted onto an upper surface of the wiring substrate;
a heat dissipation member arranged on the upper surface of the wiring substrate so as to cover the semiconductor chip;
a fixing pin for fixing the heat dissipation member onto the upper surface of the wiring substrate;
a first heat transfer material sandwiched between a lower surface of the heat dissipation member and an upper surface of the semiconductor chip; and
a second heat transfer material sandwiched between the wiring substrate and the heat dissipation member,
wherein
the fixing pin pierces the heat dissipation member and the second heat transfer material.

2. The semiconductor device of claim 1, wherein
the first heat transfer material and the second heat transfer material are made of insulating materials.

3. The semiconductor device of claim 2, wherein
when N is an integer of 2 or more, the wiring substrate is structured so that N wiring layers and (N−1) layers of substrate materials are laminated alternately,
the fixing pin includes a head portion, a cylindrical portion having a smaller diameter than that of the head portion, and a thread portion having a smaller diameter than that of the cylindrical portion, and
a bottom surface of the cylindrical portion contacts directly or indirectly with the wiring provided on one of the N wiring layers.

4. The semiconductor device of claim 3, wherein
the wiring substrate has one layer of insulating substrate material and a wiring provided on an upper surface and a lower surface of the substrate material, and
the bottom surface of the cylindrical portion contacts directly or indirectly with the wiring provided on the upper surface of the substrate material.

5. The semiconductor device of claim 3, wherein
N is 4 or more, and the bottom surface of the cylindrical portion contacts directly or indirectly with the wiring provided on one of the wiring layers except for the top wiring layer.

6. The semiconductor device of claim 1, wherein
the fixing pin is exposed from the lower surface of the wiring substrate.

7. The semiconductor device of claim 1, further comprising:
an external connecting terminal on the lower surface of the wiring substrate, wherein
the external connecting terminal is a soldering ball arranged on the lower surface of the wiring substrate into a matrix pattern.

8. The semiconductor device of claim 7, wherein
the fixing pin protrudes from the lower surface of the wiring substrate, and a length of the protruded portion of the fixing pin is equal to a height of the soldering ball.

9. The semiconductor device of claim 1, wherein
the second heat transfer material is made of an insulating material with heat conductivity and elasticity.

10. The semiconductor device of claim 1, wherein
the fixing pin fixes a peripheral portion of the heat dissipation member onto a peripheral portion of the wiring substrate.

11. The semiconductor device of claim 1, wherein
the semiconductor chip is flip-chip connected onto the wiring substrate with a circuit formed surface facing down, and
the first heat transfer material is provided on a surface of the semiconductor chip facing the circuit formed surface.

12. The semiconductor device of claim 1, further comprising:
an encapsulation resin,
wherein
the semiconductor chip is mounted onto the wiring substrate with the circuit formed surface facing up, and is encapsulated by the encapsulation resin, and
the first heat transfer material is provided between the lower surface of the heat dissipation member just above the semiconductor chip and the encapsulation resin.
